(19) United States
(12) Patent Application Publication
(10) Pub. No.: US 2025/0040443 A1
(43) Pub. Date: Jan. 30, 2025

(54) METHOD OF MANUFACTURING MAGNETIC MEMORY DEVICE

(71) Applicant: Samsung Electronics Co., Ltd., Suwon-si (KR)

(72) Inventors: Unghwan Pi, Suwon-si (KR); Stuart Papworth Parkin, Munchen (DE); Jaechun Jeon, Munchen (DE); Jaekeun Kim, Munchen (DE); Andrea Migliorini, Munchen (DE)

(73) Assignees: Samsung Electronics Co., Ltd., Suwon-si (KR); Max-Planck-Gesellschaft zur Forderung der Wissenschaften e.V., Munchen (DE)

(21) Appl. No.: 18/776,690

(22) Filed: Jul. 18, 2024

(30) Foreign Application Priority Data
Jul. 27, 2023 (KR) 10-2023-0098359

(51) Int. Cl. H10N 50/01; H10B 61/00; H10N 50/10

(52) U.S. Cl. CPC H10N 50/01; H10B 61/00; H10N 50/10

(57) ABSTRACT

According to a method of manufacturing a magnetic memory device, various types of magnetic memory devices can be manufactured at low cost by manufacturing a plurality of magnetic modules by using a delamination phenomenon of pattern segments and stacking the plurality of magnetic modules to complete a stacked memory device.

### CROSS-REFERENCE TO RELATED APPLICATION

This application claims priority under 35 U.S.C. § 119 to Korean Patent Application No. 10-2023-0098359, filed on Jul. 27, 2023, in the Korean Intellectual Property Office, the disclosure of which is incorporated by reference herein in its entirety.

### FIELD

The inventive concept relates to a method of manufacturing a magnetic memory device, and more particularly, to a method of manufacturing a magnetic memory device including a race track.

### BACKGROUND

To meet demand for miniaturization, multifunctionality, and high performance of electronic products, high-capacity memory devices are being developed. In order to provide high capacity, a race track including a plurality of magnetic domains and storing information by movement of a magnetic domain wall between the magnetic domains has been proposed. Also, a magnetic domain wall shift register type memory device including such a race track is being developed. Various methods are being proposed to manufacture high-integration magnetic memory devices at low cost.

### SUMMARY

The inventive concept provides a method of manufacturing a magnetic memory device, by which various types of magnetic memory devices may be manufactured at low cost by manufacturing a plurality of magnetic modules by using a delamination phenomenon of pattern segments and stacking the plurality of magnetic modules to complete a stacked memory device.

The problems to be solved by the inventive concept are not limited to the problems mentioned above, and other unmentioned problems will be clearly understood by those of ordinary skill in the art from the following description.

According to an aspect of the inventive concept, there is provided a method of manufacturing a magnetic memory device, the method including forming a first pattern segment on an upper surface of a base substrate, forming a first film stack on the upper surface of the base substrate and the first pattern segment and including at least one magnetic layer, forming a first stack segment by delaminating the first pattern segment and a portion of the first film stack overlapping the first pattern segment, providing the first stack segment on an upper surface of a stack substrate, patterning the first stack segment to form a first magnetic module constituting a first portion of the magnetic memory device, forming a second magnetic module constituting a second portion of the magnetic memory device by forming a second pattern segment, forming a second film stack including at least one magnetic layer on the second pattern segment, forming a second stack segment by delaminating the second pattern segment and a portion of the second film stack overlapping the second pattern segment, and patterning the second stack segment, and coupling the second magnetic module onto the first magnetic module.

According to another aspect of the inventive concept, there is provided a method of manufacturing a magnetic memory device, the method including forming each of a first magnetic module, a second magnetic module, and a third magnetic module constituting the magnetic memory device, picking up the first magnetic module by providing an adhesive stamp thereon, attaching the second magnetic module under the first magnetic module attached to the adhesive stamp, attaching the third magnetic module under the second magnetic module and opposite the first magnetic module attached to the adhesive stamp, and separating the adhesive stamp from the first magnetic module. Each of the first, second, and third magnetic modules includes a respective pattern segment in which a two-dimensional sheet material including a hexagonal boron nitride is stacked in multiple layers.

According to another aspect of the inventive concept, there is provided a method of manufacturing a magnetic memory device, the method including forming each of a first magnetic module, a second magnetic module, and a third magnetic module constituting the magnetic memory device, picking up the first magnetic module by providing an adhesive stamp thereon, attaching the first magnetic module onto an upper surface of a stack substrate, and separating the adhesive stamp from the first magnetic module, picking up the second magnetic module by providing the adhesive stamp thereon, attaching the second magnetic module onto the first magnetic module, and separating the adhesive stamp from the second magnetic module, picking up the third magnetic module by providing the adhesive stamp thereon, attaching the third magnetic module onto the second magnetic module, and separating the adhesive stamp from the third magnetic module. Each of the first, second, and third magnetic modules includes a respective pattern segment in which a two-dimensional sheet material including a hexagonal boron nitride is stacked in multiple layers.

### BRIEF DESCRIPTION OF THE DRAWINGS

Embodiments will be more clearly understood from the following detailed description taken in conjunction with the accompanying drawings in which:

FIG. 1 is a flowchart illustrating a magnetic memory device manufacturing method according to an embodiment;

FIGS. 2, 3, 4, 5, 6, 7, 8, 9, and 10 are perspective views illustrating a magnetic memory device manufacturing method according to an embodiment in process sequence;

FIG. 11 is a flowchart illustrating a magnetic memory device manufacturing method according to another embodiment;

FIGS. 12A, 12B, 12C, 12D, 12E, and 12F are perspective views illustrating a magnetic memory device manufacturing method according to another embodiment in process sequence;

FIG. 13 is a flowchart illustrating a magnetic memory device manufacturing method according to another embodiment;

FIGS. 14A, 14B, 14C, 14D, 14E, 14F, and 14G are perspective views illustrating a magnetic memory device manufacturing method according to another embodiment in process sequence; and

FIG. 15 is a perspective view illustrating a stack structure of a magnetic memory device according to an embodiment.

### DETAILED DESCRIPTION OF EMBODIMENTS

Hereinafter, embodiments will be described in detail with reference to the accompanying drawings. The terms “comprises,” “comprising,” “includes” and/or “including,” when used herein, specify the presence of stated elements, but do not preclude the presence of additional elements. The term “and/or” includes any and all combinations of one or more of the associated listed items. Components or layers described with reference to “overlap” in a particular direction may be at least partially obstructed by one another when viewed along a line extending in the particular direction or in a plane perpendicular to the particular direction.

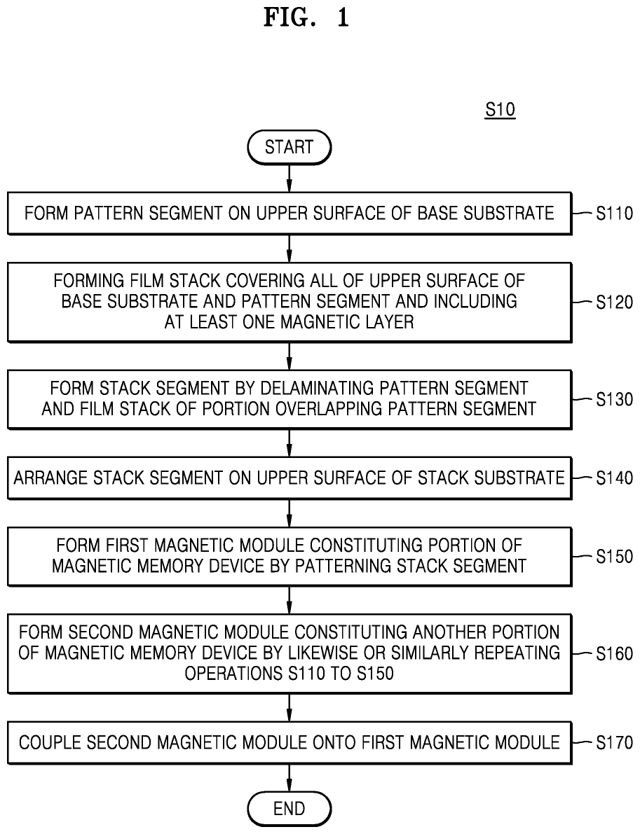

FIG. 1 is a flowchart illustrating a magnetic memory device manufacturing method according to an embodiment.

Referring to FIG. 1, a magnetic memory device manufacturing method S10 may include a process sequence of first to seventh operations S110 to S170. The terms “first,” “second,” etc., may be used herein merely to distinguish one component, layer, direction, operation, etc. from another.

Some embodiments may be implemented differently than shown and described in the examples herein. For example, a particular process order may be performed differently from the described order or the order illustrated in the flowchart. For example, two processes described or illustrated in succession may be performed substantially at the same time or may be performed in an order opposite to the described or illustrated order.

The magnetic memory device manufacturing method S10 according to the inventive concept may include a first operation S110 of forming a pattern segment on an upper surface of a base substrate, a second operation S120 of forming a film stack covering up to all of the upper surface of the base substrate and the pattern segment and including at least one magnetic layer, a third operation S130 of forming a stack segment by delaminating the pattern segment and the film stack (or a portion thereof) overlapping the pattern segment, a fourth operation S140 of arranging the stack segment on an upper surface of a stack substrate, a fifth operation S150 of forming a first magnetic module constituting a portion (e.g., a first portion) of the magnetic memory device by patterning the stack segment, a sixth operation S160 of forming a second magnetic module constituting another portion (e.g., a second portion) of the magnetic memory device by likewise or similarly repeating the first to fifth operations S110 to S150, and a seventh operation S170 of coupling the second magnetic module onto the first magnetic module.

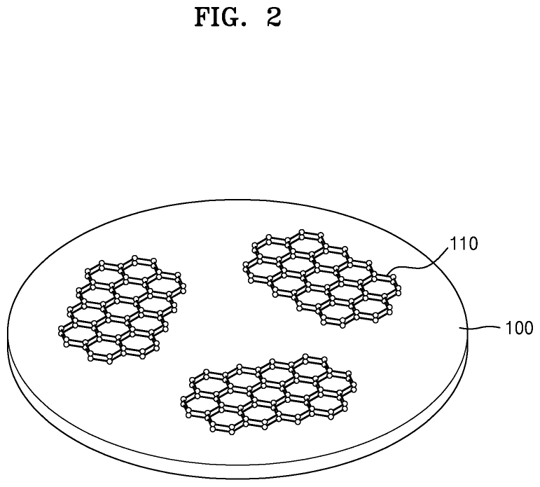

Technical features of each of the first to seventh operations S110 to S170 will be described below in detail with reference to FIGS. 2 to 10.

FIGS. 2 to 10 are perspective views illustrating a magnetic memory device manufacturing method according to an embodiment in process sequence.

Referring to FIG. 2, a plurality of pattern segments 110 may be formed on the upper surface of a base substrate 100.

In some embodiments, the base substrate 100 may be a wafer including silicon (Si), for example, crystalline silicon, polycrystalline silicon, or amorphous silicon. In some embodiments, the base substrate 100 may be a wafer including, for example, glass, silicon, or aluminum oxide.

The plurality of pattern segments 110 may be arranged to be spaced apart from each other on the upper surface of the base substrate 100. In some embodiments, the plurality of pattern segments 110 may have a structure in which a two-dimensional sheet material including a hexagonal boron nitride (h-BN) is stacked in multiple layers. That is, the pattern segments 110 may have a stacked structure including multiple layers of a two-dimensional sheet material including h-BN.

Particularly, the boron nitride may be a compound including boron (B) and nitrogen (N) in equal proportions and may have hexagonal, cubic, and wurtzite crystal forms. Here, the hexagonal boron nitride (h-BN) may be a material that is high in thermal conductivity, excellent in chemical stability, resistance to thermal shock, and excellent in mechanical strength. The hexagonal boron nitride (h-BN) may have a single-layer material structure including boron (B) atoms and nitrogen (N) atoms in a hexagonal lattice structure, that is, a two-dimensional sheet structure. In this regard, the hexagonal boron nitride (h-BN) may be similar to graphene including carbon (C) atoms in a hexagonal lattice structure. As described below, the magnetic memory device manufacturing method of the inventive concept may be described and achieved by using the delamination characteristics of the hexagonal boron nitride (h-BN).

In the plurality of pattern segments 110, a two-dimensional sheet structure in which a hexagonal lattice structure is repeated may mean that boron (B) atoms and nitrogen (N) atoms are covalently bonded to form a honeycomb structure. In some embodiments, in the plurality of pattern segments 110, a stack structure of the hexagonal boron nitride (h-BN) may include a structure in which an upper hexagonal lattice structure and a lower hexagonal lattice structure are alternately arranged. In some embodiments, in the plurality of pattern segments 110, a stack structure of the hexagonal boron nitride (h-BN) may include a structure in which an upper hexagonal lattice structure and a lower hexagonal lattice structure overlap each other.

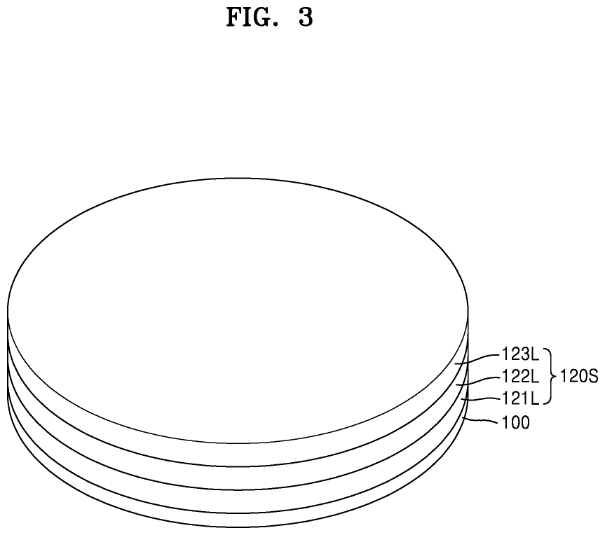

Referring to FIG. 3, a film stack 120S covering up to all of the upper surface of the base substrate 100 and the plurality of pattern segments 110 and including at least one magnetic layer may be formed. The term “covering” as may be used herein may not require completely covering the described elements or layers, but may, for example, refer to partially covering the described elements or layers

The film stack 120S may include, for example, a first film layer 121L, a second film layer 122L, and a third film layer 123L sequentially stacked over the base substrate 100. Here, at least one of the first film layer 121L, the second film layer 122L, and the third film layer 123L may include a magnetic layer including magnetic elements.

In some embodiments, in the first film layer 121L, the film stack 120S may be formed as a current layer, the second film layer 122L may be formed as a magnetic layer, and the third film layer 123L may be formed as a wiring layer.

Particularly, the first film layer 121L may have a current layer for generating spin orbit torque (SOT) by a current flowing in the first film layer 121L. In some embodiments, the first film layer 121L may include a material capable of generating a spin hall effect or a Rashia effect by a current flowing in the first film layer 121L. Also, the first film layer 121L may include a heavy metal with an atomic number of 30 or more. For example, the first film layer 121L may include iridium (Ir), ruthenium (Ru), tantalum (Ta), platinum (Pt), palladium (Pd), bismuth (Bi), titanium (Ti), or tungsten (W); however, the inventive concept is not limited thereto.

Also, the second film layer 122L may include a magnetic track layer. For example, the second film layer 122L may include at least one of cobalt (Co), iron (Fe), and nickel (Ni); however, the inventive concept is not limited thereto. The second film layer 122L may include magnetic domains (not illustrated) and a magnetic domain wall (not illustrated) between the magnetic domains. In the second film layer 122L, the magnetic domain may be an area in which magnetic moments are aligned in a certain direction. Also, in the second film layer 122L, the magnetic domain wall may be an area in which the direction of magnetic moment changes between the magnetic domains. In the second film layer 122L, the magnetic domains and the magnetic domain walls may be alternately arranged.

Also, the third film layer 123L may include a read and/or write line layer. The third film layer 123L may include, for example, copper (Cu), aluminum (Al), tungsten (W), titanium (Ti), tantalum (Ta), palladium (Pd), platinum (Pt), molybdenum (Mo), metal silicide, or any combination thereof; however, the inventive concept is not limited thereto.

Here, each of the first film layer 121L, the second film layer 122L, and the third film layer 123L may be formed by using a chemical vapor deposition (CVD) process, a physical vapor deposition (PVD) process, or an atomic layer deposition (ALD) process.

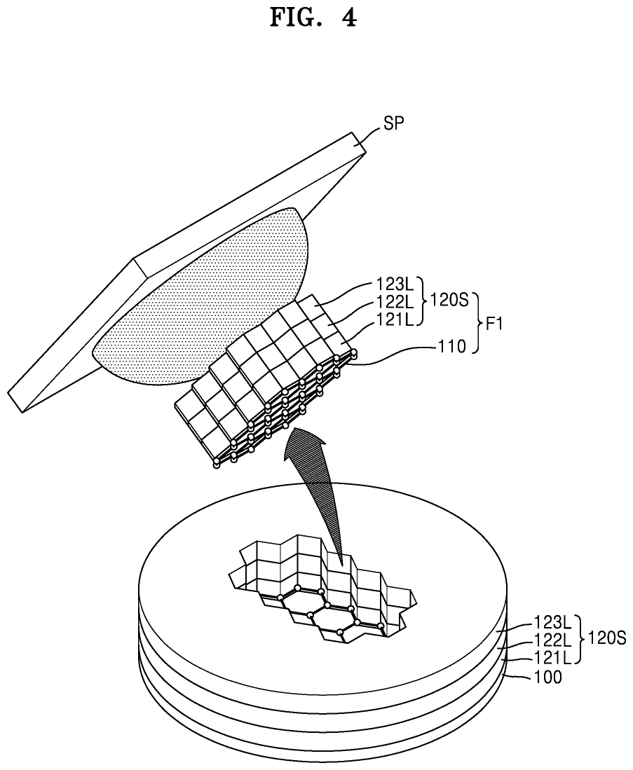

Referring to FIG. 4, a stack segment F1 may be formed by delaminating a pattern segment 110 and a film stack 120S of a portion overlapping the pattern segment 110.

By using an adhesive stamp SP over the film stack 120S of a portion overlapping a pattern segment 110 among the plurality of pattern segments 110, some layers of the film stack 120S may be removed by delaminating some layers of a two-dimensional sheet material including a hexagonal boron nitride (h-BN) constituting the pattern segment 110. That is, the adhesive stamp SP may be adhered to a portion of the film stack 120S overlapping the pattern segment 110, and lifting of the adhesive stamp SP may delaminate the portion of the film stack 120S and the pattern segment 110.

In greater detail, a pattern segment 110 may include a plurality of layers of two-dimensional sheet materials, which may be coupled to each other by a Van Der Waals force between the two-dimensional sheet materials. Because an adhesive force of the adhesive stamp SP acts greater than the Van Der Waals force, some layers of the two-dimensional sheet material may be delaminated from the other layers. In this way, the two-dimensional shape of the stack segment F1 picked up by the adhesive stamp SP may be similar to the two-dimensional shape of the pattern segment 110.

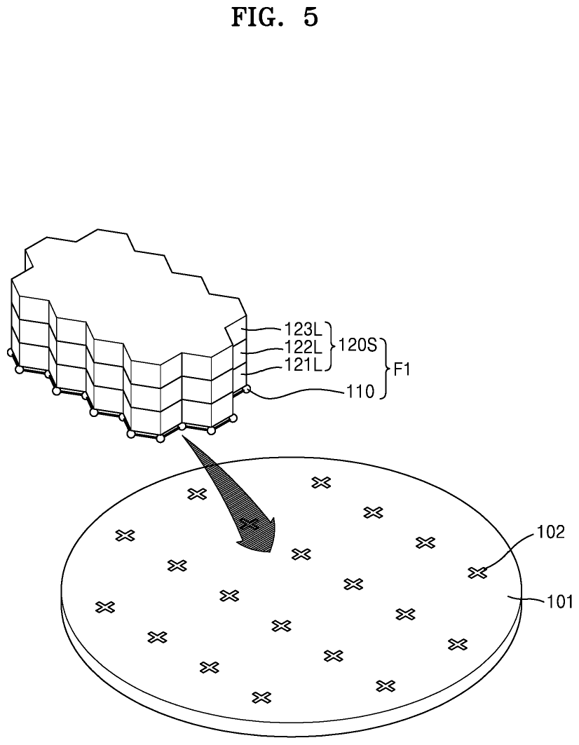

Referring to FIG. 5, the stack segment F1 attached to the adhesive stamp SP may be moved and arranged on the upper surface of a stack substrate 101.

In some embodiments, the stack substrate 101 may be a wafer including silicon (Si), for example, crystalline silicon, polycrystalline silicon, or amorphous silicon. In some embodiments, the stack substrate 101 may be a wafer including, for example, glass, silicon, or aluminum oxide. Also, a marker pattern 102 indicating a position where the stack segment F1 is to be arranged may be marked on the upper surface of the stack substrate 101.

The marker pattern 102 may have various shapes such as a dot pattern, a circular pattern, or a cross pattern, and adjacent marker patterns 102 may be arranged apart from each other at equal intervals. In some embodiments, the marker pattern 102 may protrude from the upper surface of the stack substrate 101. In some embodiments, the marker pattern 102 may be printed on the upper surface of the stack substrate 101.

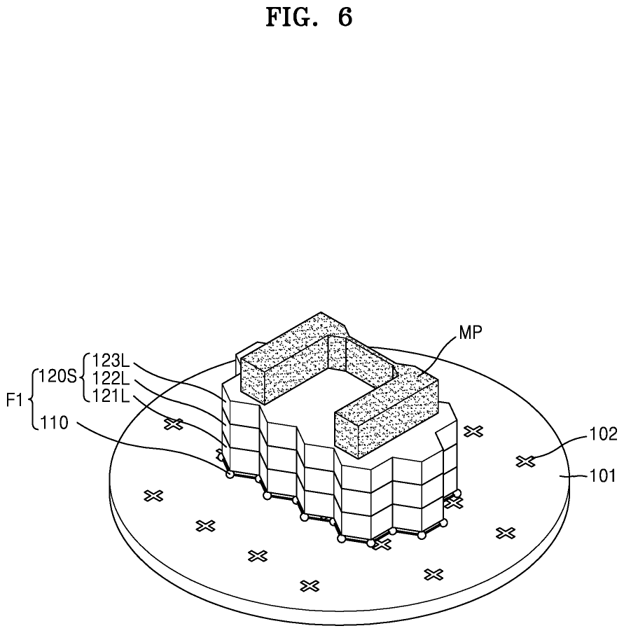

Referring to FIG. 6, after positioning the stack segment F1 at the desired region (e.g., corresponding to one or more marker patterns 102) on the upper surface of the stack substrate 101, the adhesive stamp SP (see FIG. 5) may be separated from the stack segment F1, thereby transferring the stack segment F1 to the upper surface of the stack substrate 101, and a mask pattern MP may be formed on the stack segment F1.

First, the adhesive stamp SP (see FIG. 5) may be separated from the stack segment F1, and adhesive residue that may be present over the stack segment F1 may be removed. A process of removing the adhesive residue may be performed through a cleaning process and/or an annealing process. In some embodiments, a dichloromethane solution may be used in the cleaning process; however, the inventive concept is not limited thereto. The cleaning process and/or the annealing process may be performed in an environment that has minimum impact on the material constituting the stack segment F1.

Next, the mask pattern MP may be formed over the cleaned stack segment F1 by using a photolithography process. The mask pattern MP may be a photoresist pattern or a hardmask pattern. Because a process of forming the mask pattern MP is apparent to those of ordinary skill in the art, redundant descriptions thereof will be omitted for conciseness.

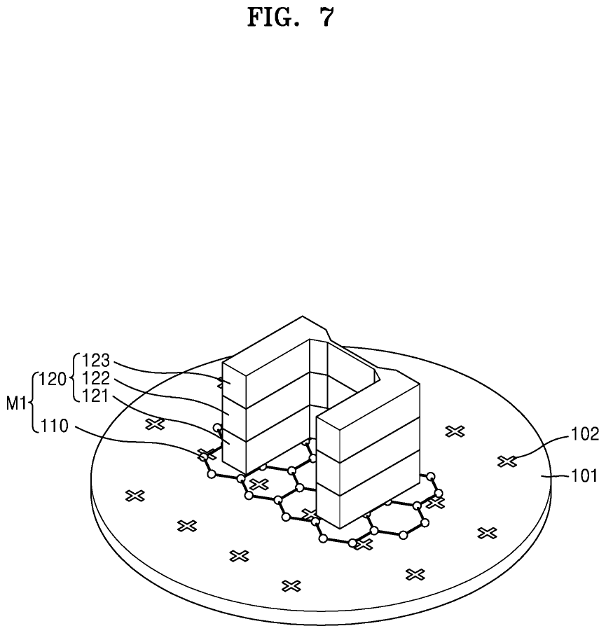

Referring to FIG. 7, a first magnetic module M1 may be formed by etching the film stack 120S (see FIG. 6) by using the mask pattern MP (see FIG. 6) as an etch mask.

The first magnetic module M1 in which a magnetic structure 120 is arranged over the pattern segment 110 may be formed by sequentially etching the third film layer 123L (see FIG. 6), the second film layer 122L (see FIG. 6), and the first film layer 121L (see FIG. 6) by using the mask pattern MP (see FIG. 6) as an etch mask.

The first magnetic module M1 may include a current layer segment 121, a magnetic layer segment 122, and a wiring layer segment 123 over the pattern segment 110. It is illustrated that the current layer segment 121, the magnetic layer segment 122, and the wiring layer segment 123 have the same shape; however, the inventive concept is not limited thereto.

For example, by first etching the third film layer 123L (see FIG. 6) by using the mask pattern MP (see FIG. 6) as an etch mask, forming a second mask pattern different from the mask pattern MP (see FIG. 6) over the second film layer 122L (see FIG. 6), and second etching the second film layer 122L (see FIG. 6) by using the second mask pattern as an etch mask, the current layer segment 121, the magnetic layer segment 122, and the wiring layer segment 123 may be manufactured to have different shapes.

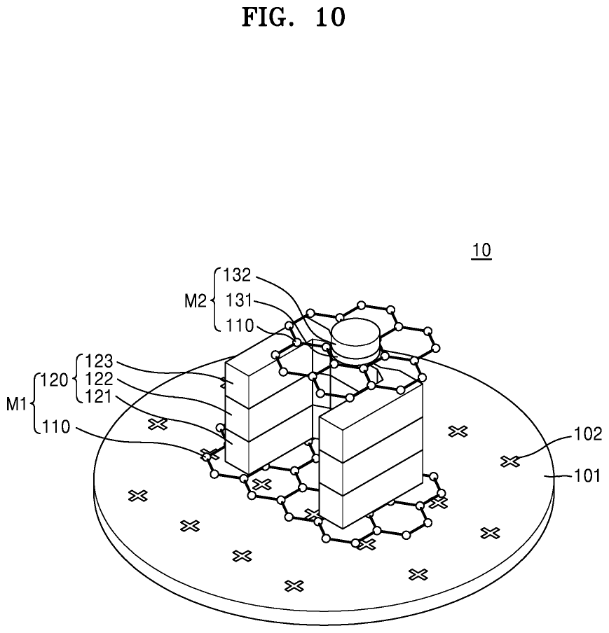

By using this method, the first magnetic module M1 as a component constituting a portion (e.g., a first portion) of a magnetic memory device 10 (see FIG. 10) may be completed.

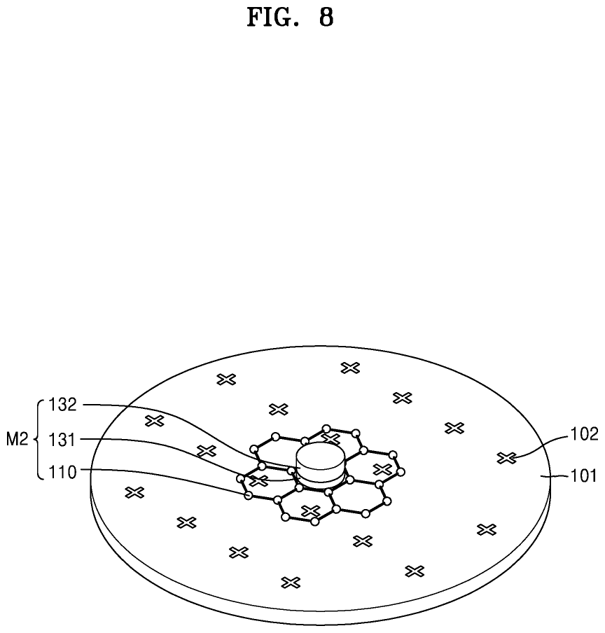

Referring to FIG. 8, by likewise or similarly repeating a manufacturing process of forming the first magnetic module M1 (see FIG. 7), a second magnetic module M2 constituting another portion (e.g., a second portion) of the magnetic memory device 10 (see FIG. 10) may be formed over the stack substrate 101. The stack substrate 101 may be a same or different substrate than the stack substrate 101 on which the first magnetic module M1 is provided.

The second magnetic module M2 may include a tunnel barrier segment 131 and a read sensor segment 132 over (e.g., stacked on) the pattern segment 110. It is illustrated that the tunnel barrier segment 131 and the read sensor segment 132 have the same shape; however, the inventive concept is not limited thereto.

Particularly, the tunnel barrier segment 131 may include an oxide of a nonmagnetic material or a nitride of a nonmagnetic material. For example, the tunnel barrier segment 131 may include at least one of MgO, TiO, AlO, MgAlO, TiN, VN, and BN; however, the inventive concept is not limited thereto. In an embodiment, the tunnel barrier segment 131 may be a portion of a magnetic tunnel junction (MTJ) structure and may constitute a tunnel barrier layer.

Also, the read sensor segment 132 may include a ferromagnetic material. For example, the read sensor segment 132 may include an alloy or a multilayer thin film of a magnetic material (CoFeB, Fe, Co, or the like) and a nonmagnetic material (Pt, Ir, Ru, Ta, W, Mo, Hf, or the like); however, the inventive concept is not limited thereto. In an embodiment, the read sensor segment 132 may be a portion of an MTJ structure and may constitute a fixed layer.

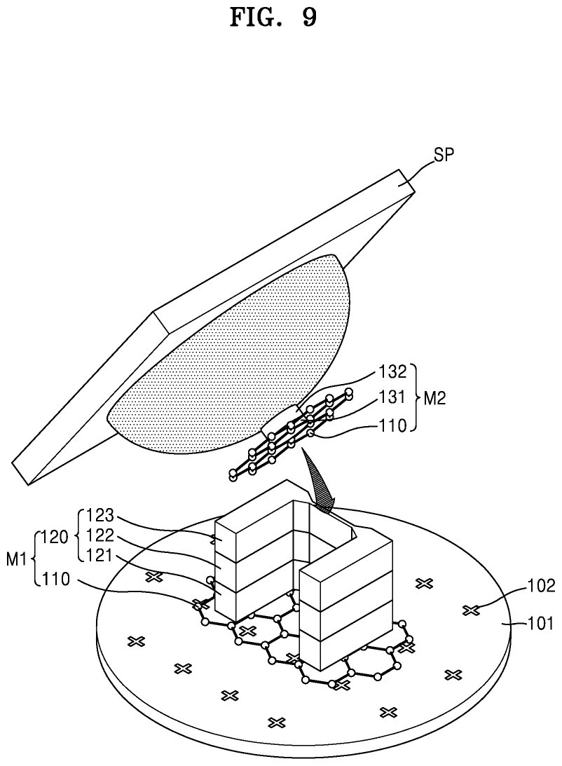

Referring to FIG. 9, by using the adhesive stamp SP, the second magnetic module M2 may be picked up and coupled onto the first magnetic module M1.

The upper surface of the first magnetic module M1 and the lower surface of the second magnetic module M2 may be attached to each other while contacting each other. The attachment of the first magnetic module M1 and the second magnetic module M2 to each other may depend on the coupling force of the pattern segment 110 located under the second magnetic module M2.

Referring to FIG. 10, a magnetic memory device 10 may be completed by separating the adhesive stamp SP (see FIG. 9) therefrom and removing adhesive residue that may be present over the second magnetic module M2.

Particularly, a process of removing the adhesive residue may be performed through a cleaning process and/or an annealing process. In some embodiments, a dichloromethane solution may be used in the cleaning process; however, the inventive concept is not limited thereto. The cleaning process and/or the annealing process may be performed in an environment that has minimum impact on the material constituting the magnetic memory device 10.

Although not illustrated, depending on the function and configuration of the magnetic memory device 10, a third magnetic module (not illustrated) may be manufactured and coupled onto the second magnetic module M2.

As noted above, to meet demand for miniaturization, multifunctionality, and high performance of electronic products, high-capacity memory devices developed. In order to provide high capacity, a race track including a plurality of magnetic domains and storing information by movement of a magnetic domain wall between the magnetic domains has been proposed. Also, a magnetic domain wall shift register type memory device including such a race track is being developed. Various methods are being proposed to manufacture high-integration magnetic memory devices at low cost.

According to the manufacturing method for the magnetic memory device 10 according to the inventive concept, a plurality of magnetic modules M1 and M2 may be manufactured by using a delamination phenomenon of a hexagonal boron nitride (h-BN) constituting a pattern segment 110 and a stacked memory device may be completed by stacking the plurality of magnetic modules M1 and M2.

Consequently, according to the manufacturing method for the magnetic memory device 10 according to the inventive concept, by modularizing each component constituting the magnetic memory device 10, various types of magnetic memory devices 10 may be manufactured at low cost.

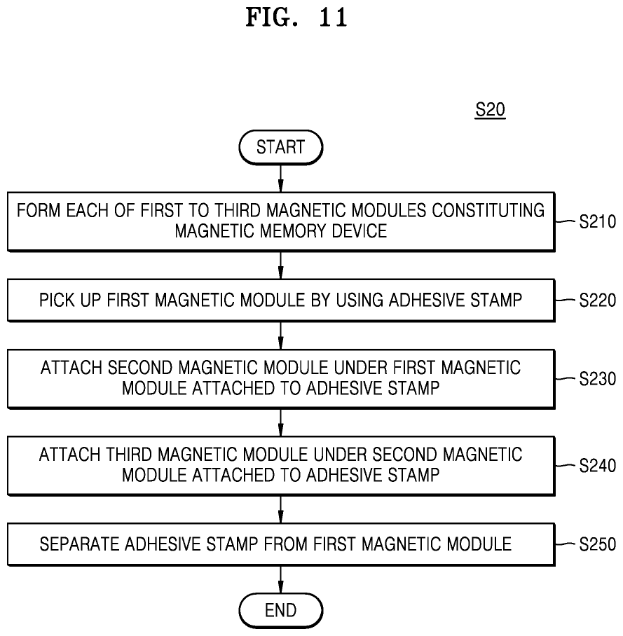

FIG. 11 is a flowchart illustrating a magnetic memory device manufacturing method according to another embodiment.

Referring to FIG. 11, a magnetic memory device manufacturing method S20 may include a process sequence of first to fifth operations S210 to S250.

When a certain embodiment may be implemented differently, a particular process order may be performed differently from the described order or the order illustrated in the flowchart. For example, two processes described or illustrated in succession may be performed substantially at the same time or may be performed in an order opposite to the described or illustrated order.

The magnetic memory device manufacturing method S20 according to the inventive concept may include a first operation S210 of forming each of first to third magnetic modules constituting a magnetic memory device, a second operation 220 of picking up the first magnetic module by using an adhesive stamp, a third operation S230 of attaching the second magnetic module under the first magnetic module attached to the adhesive stamp, a fourth operation S240 of attaching the third magnetic module under the second magnetic module and opposite the first magnetic module attached to the adhesive stamp, and a fifth operation S250 of separating the adhesive stamp from the first magnetic module.

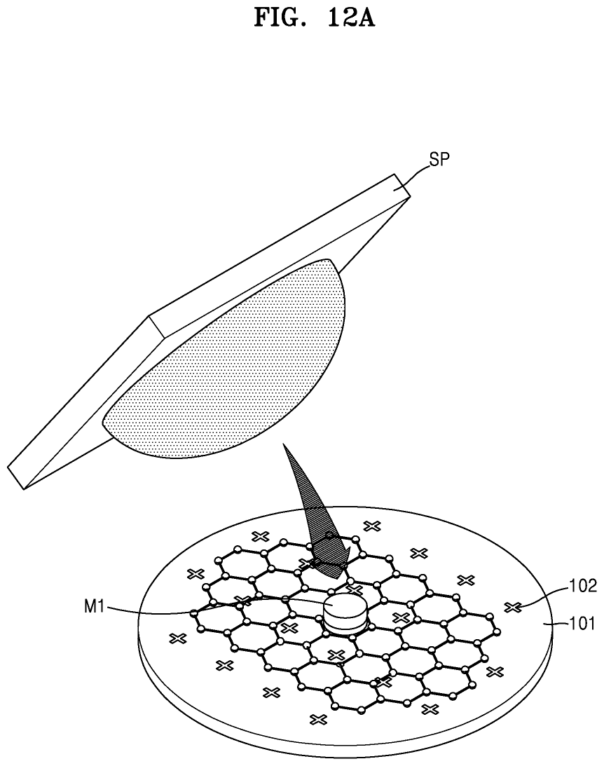

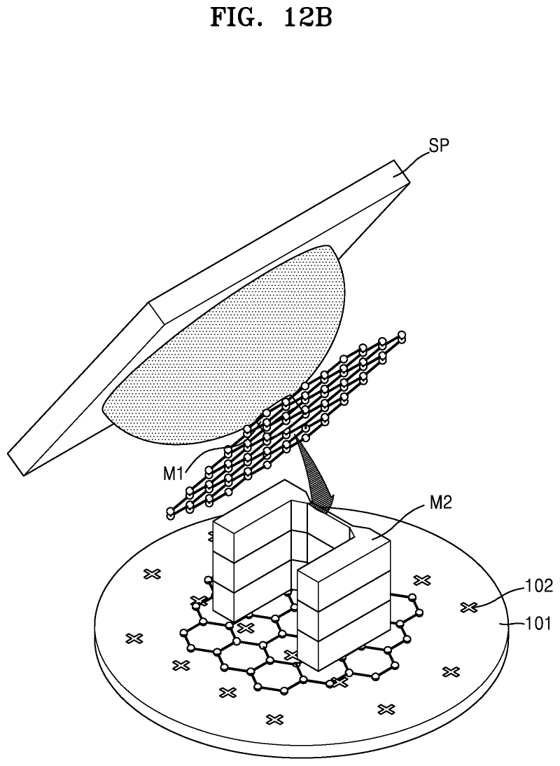

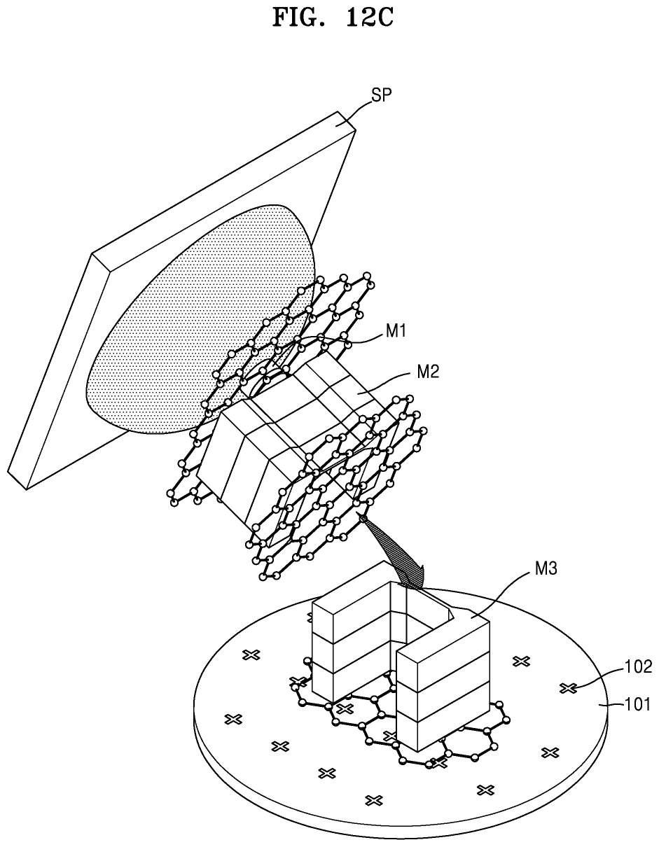

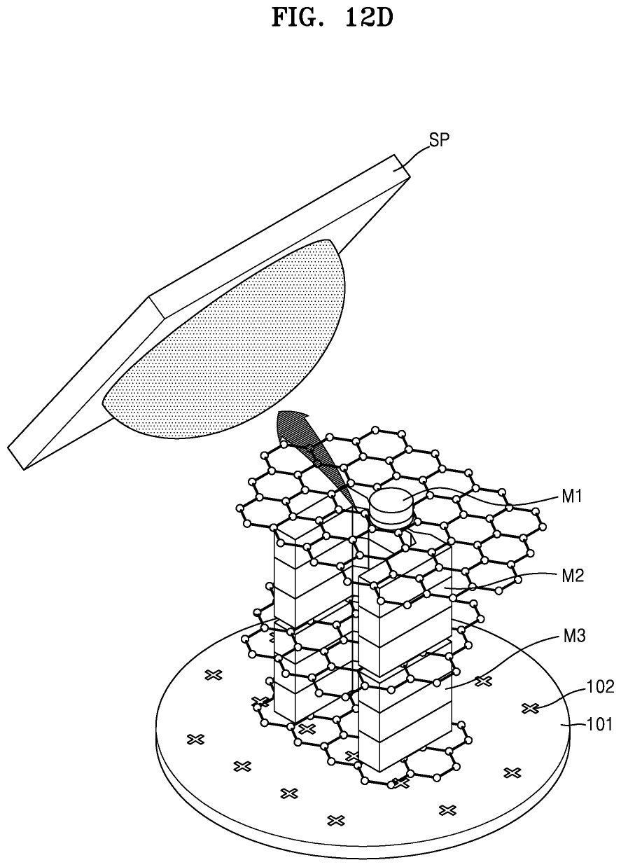

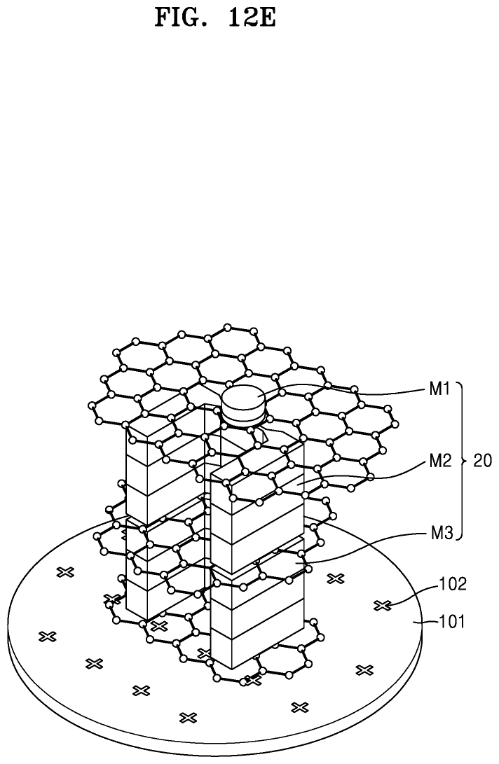

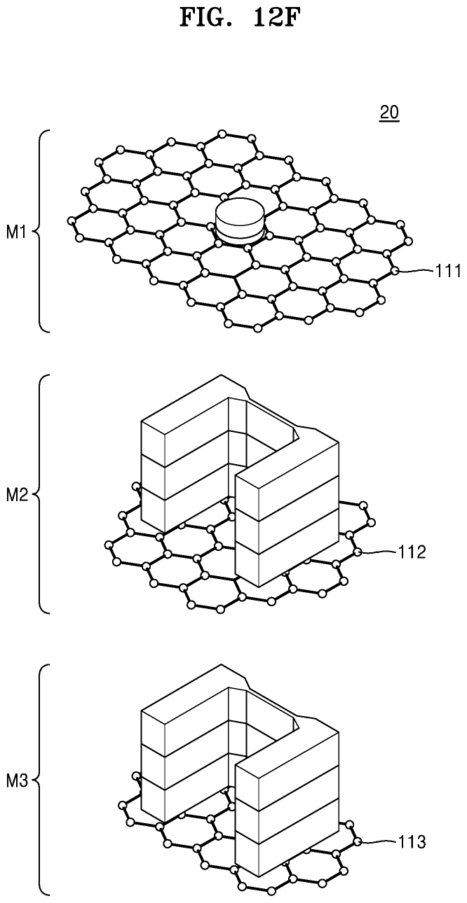

Technical features of each of the first to fifth operations S210 to S250 will be described below in detail with reference to FIGS. 12A to 12F.

FIGS. 12A to 12F are perspective views illustrating a magnetic memory device manufacturing method according to another embodiment in process sequence.

Referring to FIG. 12A, a first magnetic module M1 may be picked up from a stack substrate 101 by using an adhesive stamp SP.

Prior to this, each of a first magnetic module M1, a second magnetic module M2 (see FIG. 12B), and a third magnetic module M3 (see FIG. 12C) constituting a magnetic memory device 20 (see FIG. 12E) may be formed. Because the first to third magnetic modules M1, M2, and M3 may be formed by likewise or similarly repeating the method described above with reference to FIGS. 2 to 7, redundant descriptions thereof will be omitted for conciseness.

The first magnetic module M1 may be an uppermost component of the magnetic memory device 20 (see FIG. 12E). That is, the uppermost component may be first picked up by using the adhesive stamp SP.

Referring to FIG. 12B, the second magnetic module M2 may be attached under the first magnetic module M1 attached to the adhesive stamp SP.

First, the first magnetic module M1 attached to the adhesive stamp SP may be moved onto the second magnetic module M2 arranged over the stack substrate 101 (which may be a same or different substrate than that of the first magnetic module M1).

Next, the lower surface of the first magnetic module M1 and the upper surface of the second magnetic module M2 may be attached to each other while contacting each other. The attachment of the first magnetic module M1 and the second magnetic module M2 to each other may depend on the coupling force of a pattern segment located under the first magnetic module M1.

Referring to FIG. 12C, the third magnetic module M3 may be attached under the first magnetic module M1 and the second magnetic module M2 attached to the adhesive stamp SP.

First, the first magnetic module M1 and the second magnetic module M2 attached to the adhesive stamp SP may be moved onto the third magnetic module M3 arranged over the stack substrate 101 (which may be a same or different substrate than that of the second magnetic module M2 and/or the first magnetic module M1).

Next, the lower surface of the second magnetic module M2 and the upper surface of the third magnetic module M3 may be attached to each other while contacting each other. The attachment of the second magnetic module M2 and the third magnetic module M3 to each other may depend on the coupling force of a pattern segment located under the second magnetic module M2.

Referring to FIG. 12D, the adhesive stamp SP may transfer the first to third magnetic modules M1, M2, and M3 to a desired position on the stack substrate 101, and then the adhesive stamp SP may be separated from the first magnetic module M1.

Because each of the first to third magnetic modules M1, M2, and M3 may be more strongly coupled to each other by the coupling force of the pattern segment located thereunder, only the adhesive stamp SP may be completely separated from the first to third magnetic modules M1, M2, and M3 without separation of the first to third magnetic modules M1, M2, and M3. That is, a coupling force between the respective magnetic modules M1, M2, and/or M3 may be greater than an adhesion strength between the adhesion stamp SP and the one of the respective magnetic modules M1, M2, or M3 attached thereto.

Referring to FIG. 12E, a magnetic memory device 20 may be completed by separating the adhesive stamp SP (see FIG. 12D) therefrom and removing adhesive residue that may be present over the first magnetic module M1.

Particularly, a process of removing the adhesive residue may be performed through a cleaning process and/or an annealing process. In some embodiments, a dichloromethane solution may be used in the cleaning process; however, the inventive concept is not limited thereto. The cleaning process and/or the annealing process may be performed in an environment that has minimum impact on the material constituting the magnetic memory device 20.

As such, the magnetic memory device 20 may be formed by stacking the first to third magnetic modules M1, M2, and M3 from top to bottom, that is, by sequentially stacking the magnetic modules M1, M2, and M3. Finally, the magnetic memory device 20 may be completed by separating the magnetic memory device 20 from the stack substrate 101.

The first to third magnetic modules M1, M2, and M3 constituting the magnetic memory device 20 will be described below in detail with reference to FIG. 12F.

As described above, because the magnetic memory device 20 is formed by sequentially stacking the first to third magnetic modules M1, M2, and M3 from top to bottom, as a module is closer to the adhesive stamp SP (see FIG. 12D), the module should be designed to have a stronger coupling force with a module thereunder.

Accordingly, the areas of pattern segments for providing the coupling force in the first to third magnetic modules M1, M2, and M3 may be different from each other. For example, a first area (e.g., a first surface area) of a first pattern segment 111 of the first magnetic module M1 may be greater than a second area (e.g., a second surface area) of a second pattern segment 112 of the second magnetic module M2. Also, the second area of the second pattern segment 112 of the second magnetic module M2 may be greater than a third area (e.g., a third surface area) of a third pattern segment 113 of the third magnetic module M3.

By using the difference between the coupling forces according to the difference between the areas (e.g., the respective surface areas) of the first to third pattern segments 111, 112, and 113, only the adhesive stamp SP (see FIG. 12D) may be completely separated from the first to third magnetic modules M1, M2, and M3 without separation of the first to third magnetic modules M1, M2, and M3.

In the magnetic memory device 20 of the present embodiment, each of the second magnetic module M2 and the third magnetic module M3 may be configured to include a magnetic track layer including a plurality of magnetic domains. Also, the first magnetic module M1 may be configured to include a read sensor configured to read information of the magnetic track layer of the second magnetic module M2. However, the configuration of the first to third magnetic modules M1, M2, and M3 is not limited thereto.

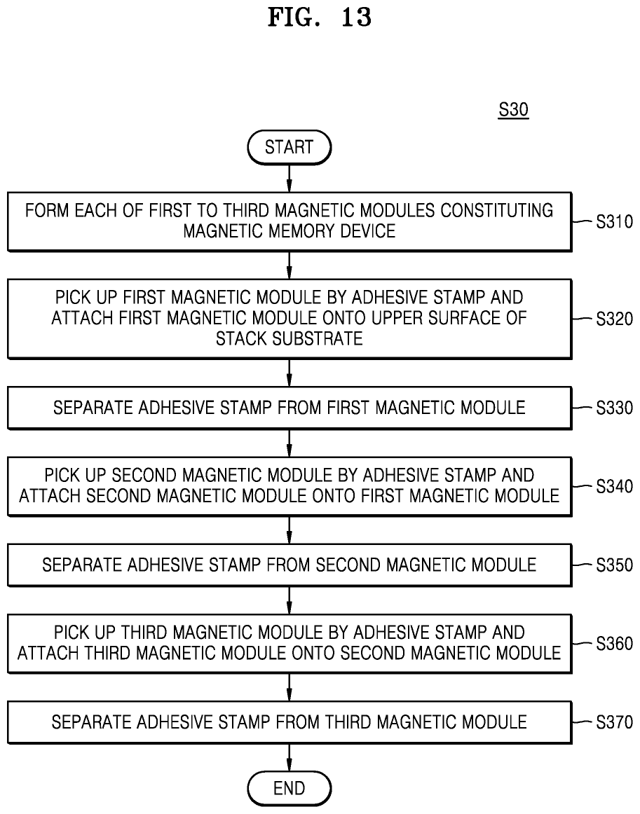

FIG. 13 is a flowchart illustrating a magnetic memory device manufacturing method according to another embodiment.

Referring to FIG. 13, a magnetic memory device manufacturing method S30 may include a process sequence of first to seventh operations S310 to S370.

When a certain embodiment may be implemented differently, a particular process order may be performed differently from the described order or the order illustrated in the flowchart. For example, two processes described or illustrated in succession may be performed substantially at the same time or may be performed in an order opposite to the described or illustrated order.

The magnetic memory device manufacturing method S30 according to the inventive concept may include a first operation S310 of forming each of first to third magnetic modules constituting a magnetic memory device, a second operation S320 of picking up the first magnetic module by an adhesive stamp and attaching the first magnetic module onto an upper surface of a stack substrate, a third operation S330 of separating the adhesive stamp from the first magnetic module, a fourth operation S340 of picking up the second magnetic module by the adhesive stamp and attaching the second magnetic module onto the first magnetic module, a fifth operation S350 of separating the adhesive stamp from the second magnetic module, a sixth operation S360 of picking up the third magnetic module by the adhesive stamp and attaching the third magnetic module onto the second magnetic module, and a seventh operation S370 of separating the adhesive stamp from the third magnetic module.

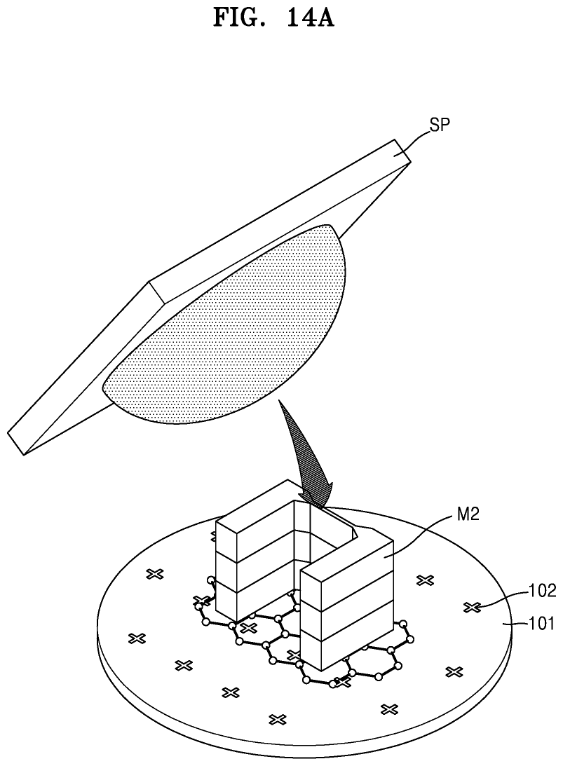

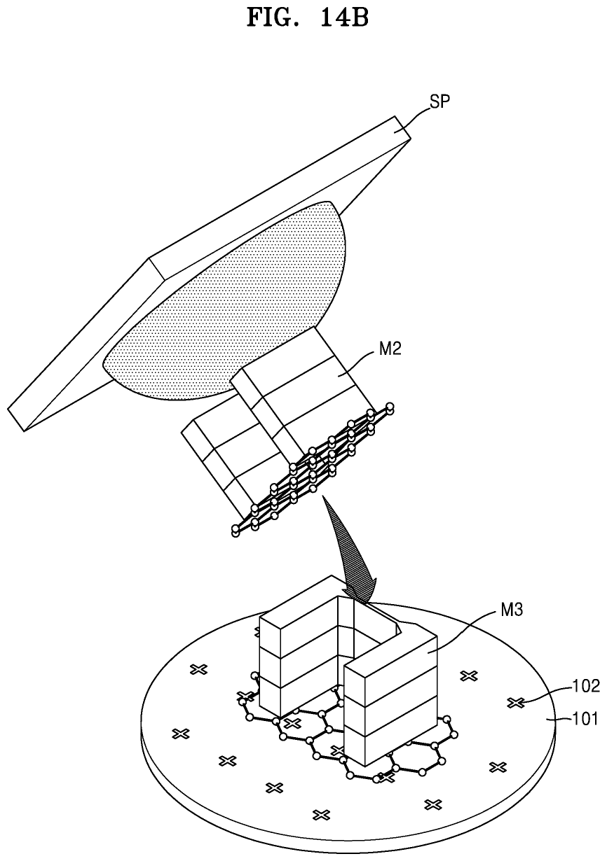

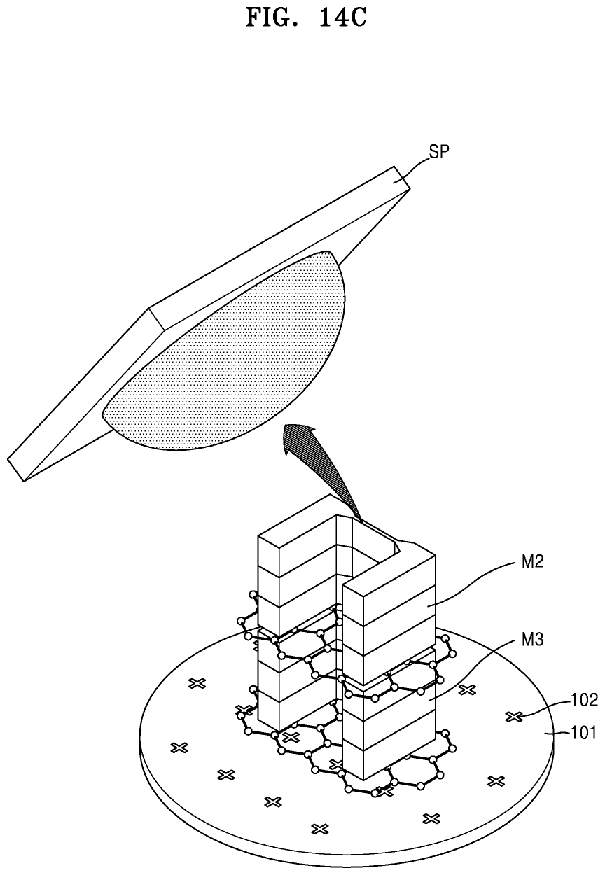

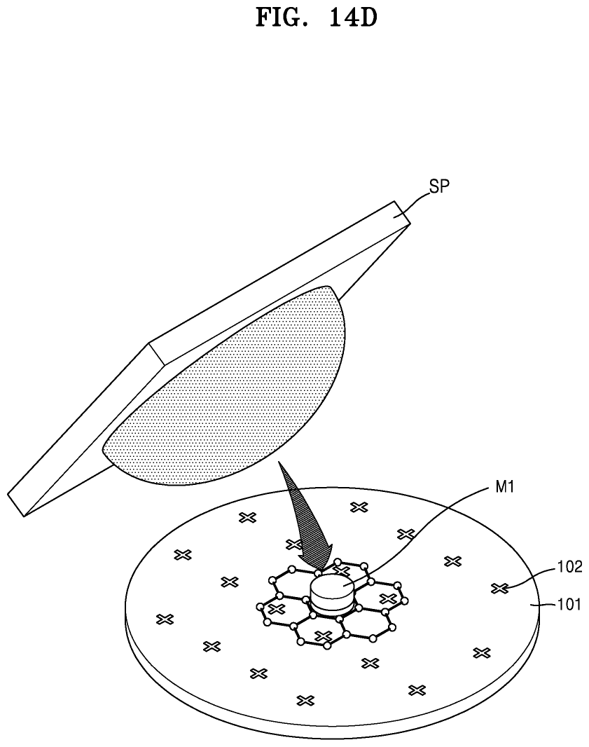

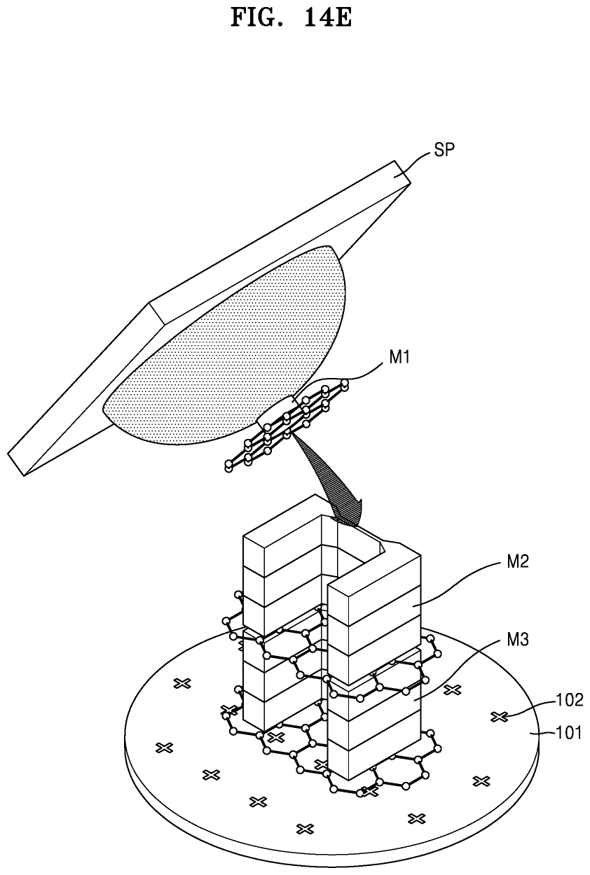

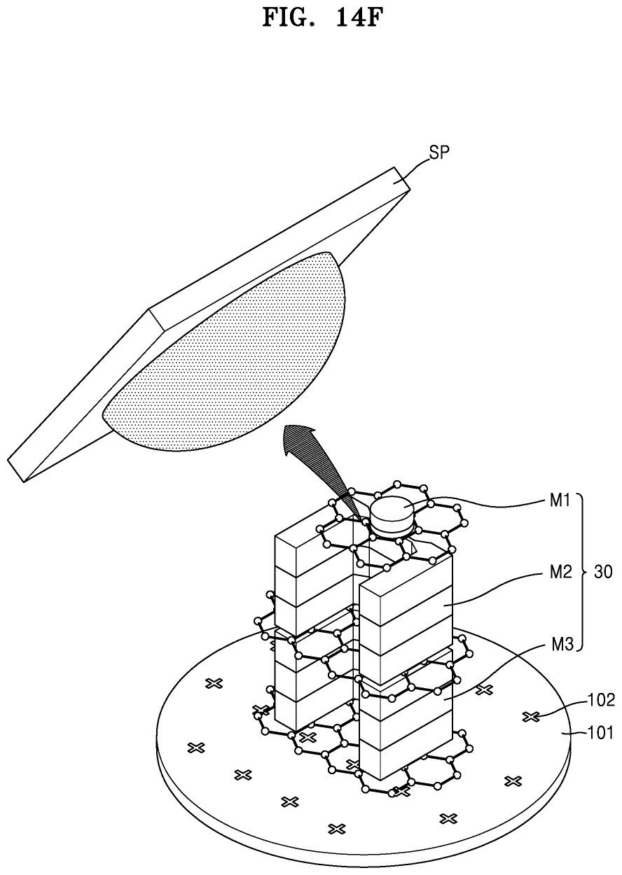

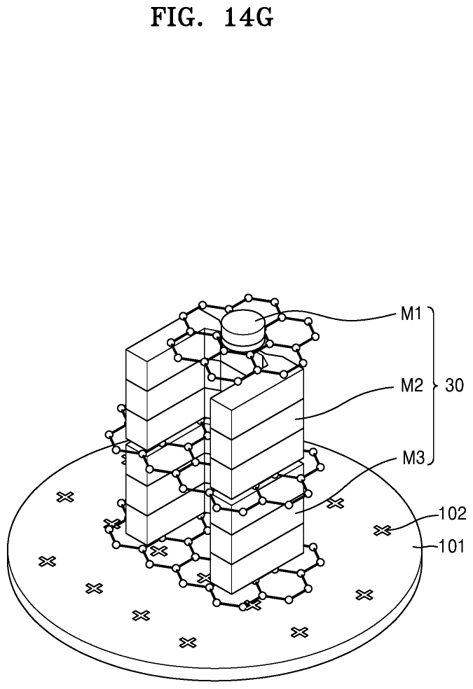

Technical features of each of the first to seventh operations S310 to S370 will be described below in detail with reference to FIGS. 14A to 14G.

FIGS. 14A to 14G are perspective views illustrating a magnetic memory device manufacturing method according to another embodiment in process sequence.

Referring to FIG. 14A, a second magnetic module M2 may be picked up from a stack substrate 101 by using an adhesive stamp SP.

Prior to this, each of a first magnetic module M1 (see FIG. 14D), a second magnetic module M2, and a third magnetic module M3 (see FIG. 14B) constituting a magnetic memory device 30 (see FIG. 14G) may be formed (e.g., on a same or different substrate). Because the first to third magnetic modules M1, M2, and M3 may be formed by likewise or similarly repeating the method described above with reference to FIGS. 2 to 7, redundant descriptions thereof will be omitted for conciseness.

Referring to FIG. 14B, the second magnetic module M2 attached to the adhesive stamp SP may be attached onto the third magnetic module M3.

First, the second magnetic module M2 attached to the adhesive stamp SP may be moved onto the third magnetic module M3 arranged over the stack substrate 101.

Next, the upper surface of the third magnetic module M3 and the lower surface of the second magnetic module M2 may be attached to each other while contacting each other. The attachment of the third magnetic module M3 and the second magnetic module M2 to each other may depend on the coupling force of a pattern segment located under the second magnetic module M2.

Referring to FIG. 14C, the adhesive stamp SP may be separated from the second magnetic module M2, and adhesive residue that may be present over the second magnetic module M2 may be removed.

Particularly, a process of removing the adhesive residue may be performed through a cleaning process and/or an annealing process. In some embodiments, a dichloromethane solution may be used in the cleaning process; however, the inventive concept is not limited thereto. The cleaning process and/or the annealing process may be performed in an environment that has minimum impact on the material constituting the third magnetic module M3 and the second magnetic module M2.

Referring to FIG. 14D, the first magnetic module M1 may be picked up from the stack substrate 101 (which may be a same or different substrate than that of the second magnetic module M2 and/or the third magnetic module M3) by using the adhesive stamp SP.

The first magnetic module M1 may be an uppermost component of the magnetic memory device 30 (see FIG. 14G). That is, the uppermost component may be last picked up by using the adhesive stamp SP.

Referring to FIG. 14E, the first magnetic module M1 attached to the adhesive stamp SP may be attached onto the second magnetic module M2.

First, the first magnetic module M1 attached to the adhesive stamp SP may be moved onto the second magnetic module M2 arranged over the stack substrate 101.

Next, the upper surface of the second magnetic module M2 and the lower surface of the first magnetic module M1 may be attached to each other while contacting each other. The attachment of the second magnetic module M2 and the first magnetic module M1 to each other may depend on the coupling force of a pattern segment located under the first magnetic module M1.

Referring to FIG. 14F, the adhesive stamp SP may be separated from the first magnetic module M1.

Because each of the first to third magnetic modules M1, M2, and M3 may be more strongly coupled to each other by the coupling force of the pattern segment located thereunder, only the adhesive stamp SP may be completely separated from the first to third magnetic modules M1, M2, and M3 without separation of the first to third magnetic modules M1, M2, and M3. That is, a coupling force between the respective magnetic modules M1, M2, and/or M3 may be greater than an adhesion strength between the adhesion stamp SP and the one of the respective magnetic modules M1, M2, or M3 attached thereto.

Referring to FIG. 14G, a magnetic memory device 30 may be completed by separating the adhesive stamp SP (see FIG. 14F) therefrom and removing adhesive residue that may be present over the first magnetic module M1.

Particularly, a process of removing the adhesive residue may be performed through a cleaning process and/or an annealing process. In some embodiments, a dichloromethane solution may be used in the cleaning process; however, the inventive concept is not limited thereto. The cleaning process and/or the annealing process may be performed in an environment that has minimum impact on the material constituting the magnetic memory device 30.

As such, the magnetic memory device 30 may be formed by sequentially stacking the first to third magnetic modules M3, M2, and M1 from bottom to top. Finally, the magnetic memory device 30 may be completed by separating the magnetic memory device 30 from the stack substrate 101.

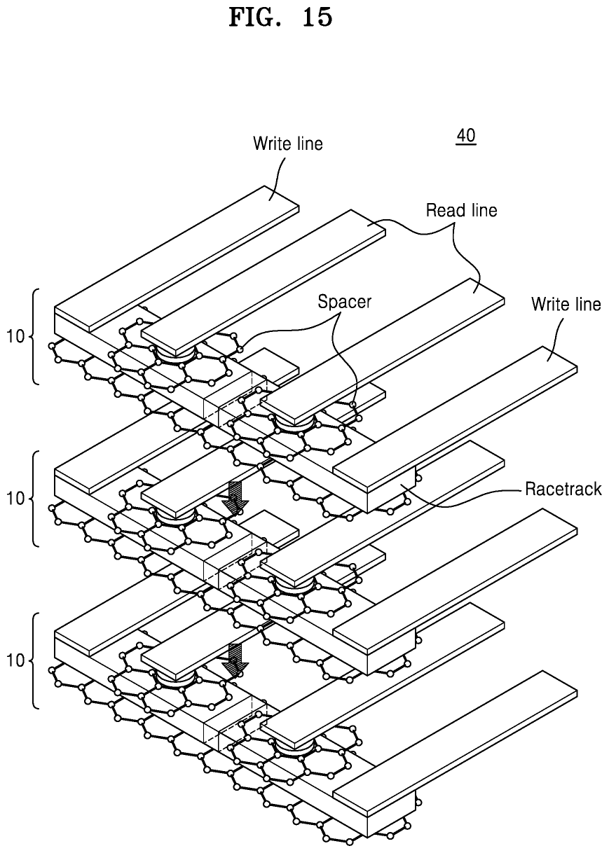

FIG. 15 is a perspective view illustrating a stack structure of a magnetic memory device according to an embodiment.

Referring to FIG. 15, a magnetic memory device 40 may be formed by stacking a plurality of magnetic memory devices 10.

In the magnetic memory device 40 of the present embodiment, each of the plurality of magnetic memory devices 10 may include a two-dimensional sheet material, a magnetic track layer arranged over the two-dimensional sheet material, write line layers arranged at both or respective ends of the magnetic track layer, read sensors arranged centrally or at the center of a magnetic domain of the magnetic track layer, and read line layers arranged over the read sensors.

The two-dimensional sheet material may include a hexagonal boron nitride (h-BN), and the two-dimensional sheet material may function as a spacer between the magnetic track layer and the read sensors.

That is, in the magnetic memory device 40 of the present embodiment, each of the plurality of magnetic memory devices 10 may be used as a module, and the magnetic memory device 40 may have a structure in which a plurality of such modules are stacked. In some embodiments, as illustrated, the magnetic memory device 40 may include a plurality of magnetic memory devices 10 of the same shape in a stack structure. In some embodiments, although not illustrated, the magnetic memory device 40 may include a plurality of magnetic memory devices 10 of different shapes in a stack structure.

It will be understood that spatially relative terms such as “over,” “above,” “upper,” “under,” “below,” “lower,” “side,” and the like may be denoted with respect to a frame of reference (e.g., a substrate) as shown the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

While the inventive concept has been particularly shown and described with reference to embodiments thereof, it will be understood that various changes in form and details may be made therein without departing from the scope of the following claims.

What is claimed is:

1. A method of manufacturing a magnetic memory device, the method comprising:
forming a first pattern segment on an upper surface of a base substrate;
forming a first film stack on the upper surface of the base substrate and the first pattern segment, the first film stack including at least one magnetic layer;
forming a first stack segment by delaminating the first pattern segment and a portion of the first film stack overlapping the first pattern segment;
providing the first stack segment on an upper surface of a stack substrate;
patterning the first stack segment to form a first magnetic module constituting a first portion of the magnetic memory device;
forming a second magnetic module constituting a second portion of the magnetic memory device by forming a second pattern segment, forming a second film stack including at least one magnetic layer on the second pattern segment, forming a second stack segment by delaminating the second pattern segment and a portion of the second film stack overlapping the second pattern segment, and patterning the second stack segment; and
coupling the second magnetic module onto the first magnetic module.

2. The method of claim 1, wherein, the first pattern segment comprises a stacked structure including multiple layers of a two-dimensional sheet material comprising hexagonal boron nitride.

3. The method of claim 2, wherein, forming the first stack segment comprises using an adhesive stamp over the portion of the first film stack overlapping the first pattern segment to remove the portion of the first film stack by delaminating some layers of the two-dimensional sheet material constituting the first pattern segment.

4. The method of claim 1, wherein, the first magnetic module includes:
a magnetic track layer comprising a plurality of magnetic domains; and
a write line layer at respective ends of the magnetic track layer.

5. The method of claim 4, wherein the second magnetic module includes:
a read sensor configured to read information of the magnetic track layer of the first magnetic module; and
a read line layer over the read sensor.

6. The method of claim 5, wherein the magnetic track layer of the first magnetic module, the second pattern segment of the second magnetic module, and the read sensor of the second magnetic module comprise a free layer, a tunnel barrier layer, and a fixed layer, respectively, of a magnetic tunnel junction structure.

7. The method of claim 1, wherein each of the base substrate and the stack substrate comprises a respective wafer, and
a marker pattern indicating a position at which the first stack segment is to be arranged is marked on the upper surface of the stack substrate.

8. The method of claim 1, further comprising:
forming a third magnetic module constituting a third portion of the magnetic memory device by forming a third pattern segment, forming a third film stack including at least one magnetic layer on the third pattern segment, forming a third stack segment by delaminating the third pattern segment and a portion of the third film stack overlapping the third pattern segment, and patterning the third stack segment; and
coupling the third magnetic module onto the second magnetic module.

9. The method of claim 8, wherein each of the first magnetic module and the second magnetic module comprises:
a magnetic track layer comprising a plurality of magnetic domains; and
a write line layer at respective ends of the magnetic track layer, and
wherein the third magnetic module comprises:
a read sensor configured to read information of the magnetic track layer of the second magnetic module; and
a read line layer over the read sensor.

10. The method of claim 9, wherein the magnetic track layer of the second magnetic module, the pattern segment of the third magnetic module, and the read sensor of the third magnetic module comprise a free layer, a tunnel barrier layer, and a fixed layer, respectively, of a magnetic tunnel junction structure.

11. A method of manufacturing a magnetic memory device, the method comprising:
forming each of a first magnetic module, a second magnetic module, and a third magnetic module constituting the magnetic memory device;
picking up the first magnetic module by providing an adhesive stamp thereon;
attaching the second magnetic module under the first magnetic module attached to the adhesive stamp;
attaching the third magnetic module under the second magnetic module and opposite the first magnetic module attached to the adhesive stamp; and
separating the adhesive stamp from the first magnetic module having the second magnetic module attached thereunder and the third magnetic module attached under the second magnetic module,
wherein each of the first, second, and third magnetic modules comprises a respective pattern segment comprising a stacked structure including multiple layers of a two-dimensional sheet material comprising hexagonal boron nitride.

12. The method of claim 11, wherein the first, second, and third magnetic modules are sequentially stacked.

13. The method of claim 12, wherein a first surface area of the respective pattern segment included in the first magnetic module is greater than a second surface area of the respective pattern segment included in the second magnetic module, and
wherein the second surface area of the respective pattern segment included in the second magnetic module is greater than a third surface area of the respective pattern segment included in the third magnetic module.

14. The method of claim 11, wherein each of the first, second, and third magnetic modules is formed through a delamination process on the respective pattern segment and a patterning process on a respective film stack over the respective pattern segment.

15. The method of claim 14, wherein each of the second magnetic module and the third magnetic module comprises:
a magnetic track layer comprising a plurality of magnetic domains; and
a write line layer at respective ends of the magnetic track layer, and
wherein the first magnetic module comprises:
a read sensor configured to read information of the magnetic track layer of the second magnetic module; and
a read line layer over the read sensor.

16. A method of manufacturing a magnetic memory device, the method comprising:
forming each of a first magnetic module, a second magnetic module, and a third magnetic module constituting the magnetic memory device;
picking up the first magnetic module by providing an adhesive stamp thereon, attaching the first magnetic module onto an upper surface of a stack substrate, and separating the adhesive stamp from the first magnetic module;
picking up the second magnetic module by providing the adhesive stamp thereon, attaching the second magnetic module onto the first magnetic module, and separating the adhesive stamp from the second magnetic module;
picking up the third magnetic module by providing the adhesive stamp thereon, attaching the third magnetic module onto the second magnetic module, and separating the adhesive stamp from the third magnetic module,
wherein each of the first, second, and third magnetic modules a respective pattern segment comprising a stacked structure including multiple layers of a two-dimensional sheet material comprising hexagonal boron nitride.

17. The method of claim 16, wherein the first, second, and third magnetic modules are sequentially stacked.

18. The method of claim 17, further comprising, after separating the adhesive stamp from the first, second, and third magnetic modules, performing a cleaning process of removing adhesive residue of the adhesive stamp from the first, second, and third magnetic modules.

19. The method of claim 16, wherein each of the first, second, and third magnetic modules is formed through a delamination process on the respective pattern segment and a patterning process on a respective film stack over the respective pattern segment.

20. The method of claim 19, wherein each of the first magnetic module and the second magnetic module comprises:
a magnetic track layer comprising a plurality of magnetic domains; and
a write line layer at respective ends of the magnetic track layer, and
wherein the third magnetic module comprises:
a read sensor configured to read information of the magnetic track layer of the second magnetic module; and
a read line layer over the read sensor.
